(19) United States
(12) Patent Application Publication
(10) Pub. No.: US 2011/0271872 A1
(43) Pub. Date: Nov. 10, 2011

(54) WEAR PROTECTION LAYER AND METHOD FOR THE MANUFACTURE THEREOF

(75) Inventor: Markus Lechthaler, Feldkirch (AT)

(73) Assignee: Oerlikon Trading AG, Trubbach, Trubbach (CH)

(21) Appl. No.: 13/127,707

(22) PCT Filed: Nov. 2, 2009
(86) PCT No.: PCT/EP2009/064443

§ 371 Date: Jul. 19, 2011

Related U.S. Application Data
(60) Provisional application No. 61/111,032, filed on Nov. 4, 2008.

(51) Int. Cl. C09D 1/00; C23C 16/50; C23C 16/448

(52) U.S. Cl. 106/286.4; 427/580; 106/286.5

(57) ABSTRACT

The invention relates to a wear protection layer for tools such as milling cutters, cutting inserts, injection molds and the like, in particular wear protection layers deposited using physical vapor deposition, said layers having the general composition AlNbX, where X stands for N, C, B, CN, BN, CBN, NO, CO, BO, CNO, BNO, or CNCO, characterized in that the Nb fraction is less than 40 at % and/or the aluminum powder used in the manufacturing process is mixed with 10 to 50 at % zirconium relative to the aluminum, and also relates to a method for manufacturing a wear protection layer.

The invention relates to a wear protection layer and a method for the manufacture thereof.

In addition to the TiAlN system that has been known for decades, the prior art also includes the AlCrN system. This system features improved mechanical, thermal, and tribological properties, which in many applications, result in an increased performance of the coated components and tools.

U.S. Pat. No. 7,226,670 has disclosed a coated part with a coating system containing at least one AlyCrl-yX system, where X stands for N, C, B, CN, BN, CBN, NO, CO, BO, CNO, BNO, or CNCO. The part described therein is a milling tool, a hob cutter, a ball-end mill, a planar or profile cutter, a reaming tool, a reamer, a thread-cutting insert, a casting mold, or an injection mold.

JP-2006225703 has disclosed a [(Nb_{1-d}Ta_{d})ₐAl_{1-a-b-c}, Si_{b}, B_{c}](C₁₋ₓNₓ) layer system with the following composition:

0≦d≦1

0.4≦a≦0.6

0≦b+c≦0.15

0.4≦x≦1.

It is known that AlCrN-containing layers display a very high oxidation resistance. In AlCrN-containing layers, the oxidation starts in the range of temperatures >1100° C. Depending on the conditions in which the layer is used, however, it is possible to hinder the formation of a stable oxide skin. Such conditions are present, for example, in a glow wire test in a vacuum or in inert gas, but also in machining applications in which the cutting edge is not directly exposed to the atmosphere or is only partially exposed to it. Conditions that describe this state can be present, for example, in a turning or drilling application.

Under such conditions, a breakdown of AlCrN into Cr2N is observed at temperatures of 800° C. and above.

AlNbN-containing layers display a comparable oxidation resistance in the vicinity of 1100° C. In addition, this system also features the decomposition into a more thermodynamically stable Nb₂N. However, this decomposition only occurs at temperatures significantly greater than 1100° C. These layers can therefore be used in application fields in which they demonstrate significantly better performance despite having comparable oxidation resistance.

The various wear mechanisms are an additional issue. The favorable mechanical, tribological, and thermal properties of NbAlN-containing layers illustrate the potential of these layers in the wear protection sector.

Depending on the wear mechanism, however, the tribochemical wear is also extremely important. The layer material's solubility in iron is thus an indication for the tribochemical wear resistance when used in contact with ferrous materials. The clear rule of thumb applies: the lower the solubility in iron, the greater the tribochemical wear resistance when used in contact with ferrous materials.

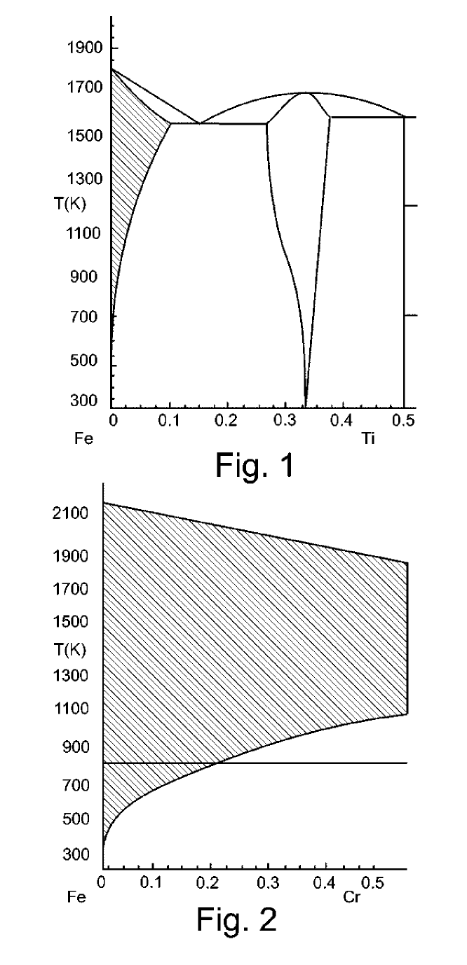

FIGS. 1 through 3 show the phase diagrams of the binary systems Fe—Ti, Fe—Cr, and Fe—Nb. The shaded area illustrates the gap-free miscibility of the two metals. When the three binary systems are compared, the Cr of the AlCrN-containing layers displays the greatest solubility in iron. The titanium of the Ti-containing layers displays a significantly lower solubility than Cr, but at high temperatures of the kind that occur in the application field of many wear protection applications, their solubility increases significantly as well. In the case of the Nb that is present in NbAlN-containing layers, this solubility is very low, even at high temperatures. Even at 1000° C., it is still less than 1 at %. This system can therefore be used to achieve an improved tribochemical wear resistance in wear-inducing contact with iron-based materials. This is the case, for example, in mechanical machining processes for steel, e.g. material removal or shaping, but also in frictional contact between parts and technical components.

Typical manufacturing methods for such layers include PVD (physical vapor deposition) processes. In particular, the arc vaporization process is preferred, whose high deposition rate and high level of ionization permits an economical depositing of high quality hard films. This process is characterized in that an arc physically vaporizes the target surface. This vaporization process means that partially vaporized particles, so-called spatter, are emitted from the target surface and this spatter can then be found in the form of so-called droplets in the layer. A high-quality vaporization process is characterized in that the amount of spatter is kept as low as possible.

However, when the percentage of Nb is too high, metallic Nb spatter ends up being incorporated into the layer, presumably due to the different melting points (melting point of Al: 660° C., melting point of Nb: 2,467° C.). Among other things, this results in a greater surface roughness, which leads to a sharply reduced wear resistance. Spatter also modifies mechanical properties such as the hardness, elasticity, etc. in a way that is unfavorable for the application.

The object of the invention is to create an improved wear protection layer that has improved mechanical properties while having very good tribochemical properties.

The object is attained with a wear protection layer having the defining characteristics of claim 1.

Advantageous modifications are disclosed in the dependent claims.

Another object of the invention is to create a method for manufacturing an improved wear protection layer that makes it possible to produce a wear protection layer with very good tribochemical properties and improved mechanical properties.

This object is attained with the defining characteristics of claim 6.

Advantageous modifications are disclosed in the claims that depend thereon.

According to the invention, the object is attained by means of a wear protection layer, which, despite the fact that its Nb content has not been entirely eliminated, has no Nb spatter or at least, has an amount of Nb spatter that has been significantly reduced by comparison to the prior art, in that the target design according to the prior art is modified so that the melting behaviors of Al and Nb at least come closer each other.

It turns out that on the one hand, this can be achieved by reducing the proportion of Nb. The amount of spatter turns out to decrease dramatically starting at a percentage-based Nb proportion of less than 40%. On the other hand, it turns out that the amount of spatter can be significantly reduced by adding zirconium to the target. In this case, Zr is mixed into the Al powder, preferably in a proportion of between 10 and 50 at %. In a further restriction, the range lies between 20 and 30 at % and ideally, the intermetallic phase Al3Zr is used, which has an atomic ratio of 75 at % Al and 25 at % of Zr.

For example, a wear protection layer according to the invention has the following composition:

Nb_{1-a-b}Alₐ(Si_{b})X, where
X is at least one element from the group N, C, B, CN, BN, CBN, NO, CO, BO, CNO, BNO, and CNCO and
the ranges for a and b are:
0.6<a≦0.9
0≦b≦0.2,
   where a >0.6 means that the material provided with the index a is present in a proportion of greater than 60 atomic percent. The same is true for the index b.

In another advantageous embodiment, the wear protection layer has the following composition:

Nb_{1-a-b}(Al_{1-c}Zr_{c})ₐ(Si_{b})X, where

X stands for N, C, B, CN, BN, CBN, NO, CO, BO, CNO, BNO, or CNCO, and
0.3<a ≦0.9
0≦b≦0.2
0.1<c≦0.5,
where a >0.3 means that the material provided with the index a is present in a proportion of greater than 30 atomic percent. The same is true for the indexes b and c.

The invention will be explained by way of example in conjunction with the drawings.

FIG. 1: shows a phase diagram of an iron-titanium system. The shaded area illustrates the solubility of titanium in iron. This solubility is an indication of the tribochemical wear resistance of a material composition; the lower the solubility, the greater the tribochemical wear resistance.

FIG. 2: shows a phase diagram of an iron-chromium system. The shaded area illustrates the solubility of chromium in iron.

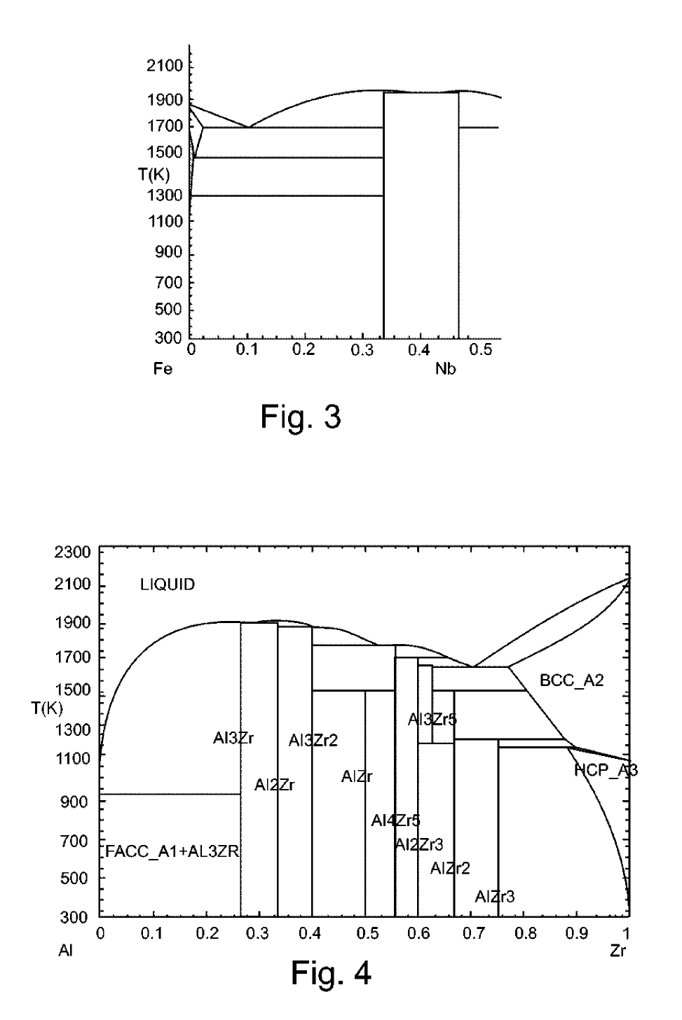

FIG. 3: shows a phase diagram of an iron-niobium system. The shaded area illustrates the solubility of niobium in iron. By contrast with titanium and chromium, niobium is virtually insoluble in iron, even at very high temperatures (1,000° C.) of the kind that occur in this application.

FIG. 4: shows a phase diagram of an aluminum zirconium system. The phase diagram clearly demonstrates that the addition of zirconium to aluminum increases the melting point. With a phase content of 75 at % Al and 25 at % Zr, a high-melting intermetallic phase occurs and immediately thereafter, a high-melting eutectic mixture occurs starting at 1595°.

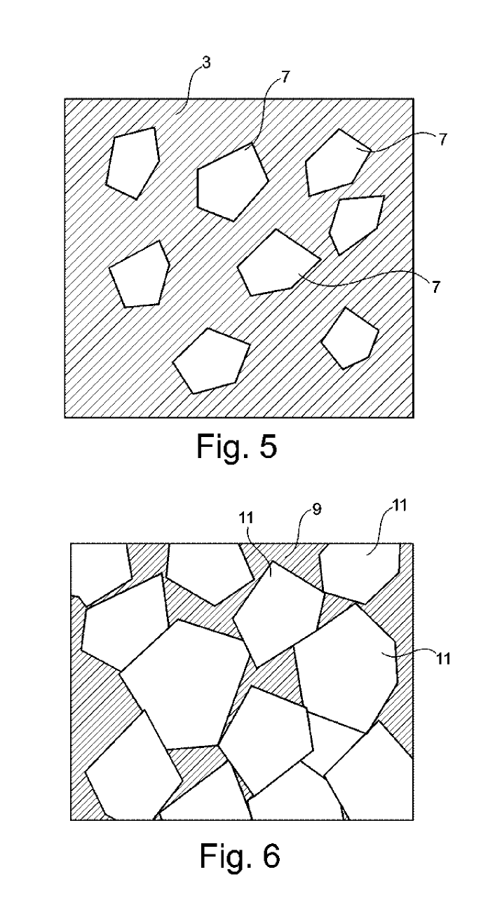

FIG. 5: schematically depicts niobium grains 7 in a continuous aluminum matrix 5 (shaded). This phase mixture is present with high aluminum contents (>60%).

FIG. 6: schematically depicts niobium grains 11 mixed with aluminum and AlZr 9 (shaded). This constellation is present with low aluminum contents (<60%). In this case, there is no continuous Al matrix. This results in a particular porosity in the target and the spatter formation can only be gotten under control through the adjusted melting points of niobium and AlZr.

The inventors have determined that with high Nb contents, the tribochemical wear properties do in fact improve compared to a system without Nb, but the mechanical wear properties deteriorate in an unacceptable fashion. This is presumably due to metallic Nb incorporated into the layer.

According to the invention, it turns out that in layers manufactured by means of arc vaporization, the spatter problem is sharply reduced without having to forfeit the advantages relating to tribochemical wear protection if—according to a first embodiment of the present invention—a Nb fraction is reduced to less than 40% and as low as 10%. With an even lower Nb fraction, there is essentially no further discernible improvement in tribochemical wear protection as compared to pure AlN.

According to a second embodiment of the present invention, a zirconium fraction is mixed into the target used for the coating. In other words, part of the aluminum in the target is replaced with zirconium. It turns out that a proportional percentage of zirconium to aluminum of less than 10% makes it possible to sharply reduce the amount of spatter. Presumably, this is due to the formation of an intermetallic AlZr phase and the attendant melting point increase. This melting point increase results in an adjustment of the melting points of Nb and of the intermetallic AlZr phase mixture. It is thus possible for the difference between the melting points of aluminum and niobium, which lies in the vicinity of von 1800° C., to be reduced to the difference of 850° C. between the melting points of aluminum-zirconium and niobium. This adjustment of the melting points then yields a significantly more stable, spatter-reducing vaporization process.

As the AlZr phase diagram clearly demonstrates to the specialist, the addition of a few percent of zirconium to aluminum yields a two-phase fine structure, namely of the high-melting aluminum-zirconium phase and the low-melting aluminum mixed crystal. The proportion of this high-melting aluminum-zirconium phase increases with the increasing zirconium content and finally, with a proportion of 25% zirconium and 75% aluminum, yields a single-phase intermetallic phase. Other comparable intermetallic phases form with an even greater increase in zirconium content. Ideally, such an intermetallic phase is mixed with niobium powder.

The above-described wear protection layers according to the invention can be used to advantageously coat parts and tools. The subject of the present invention therefore also includes such coated components. Among other things, they can include a milling tool, a hob cutter, a ball-end mill, a planar or profile cutter, a reaming tool, a reamer, a thread-cutting insert, a casting mold, or an injection mold.

Two application examples are presented in the experiments below in which the service life is expressed based on the possible machining distance. The stoichiometry in this case is expressed in atomic percent.

### Experiment 1:

### Machining Parameters:

Work piece: DIN 1.2344 (36 HRC)
Machining tool: 3-lipped end mill, Ø8 mm, fine-grained hard metal
Cutting speed: 120 rpm
Tooth advance: 0.05 mm/tooth
Radial feed: 0.5 mm
Axial feed: 10 mm
Coolant: Wet machining 6% emulsion
Milling strategy: Lateral milling
Wear criterion: v_{bmax}>120 μm
Result (maximum life of coated tool):

| | |
|---|---|
| Commercial coating | 40 m |
| Al₆₀Nb₄₀N | 50 m |
| Al₈₀Nb₂₀N | 60 m |
| AL₄₀Nb₆₀N | 35 m |
| Al₄₅Nb₄₅Zr₁₀N | 55 m |
| Al₇₀Nb₂₀Si₁₀N | 60 m |

### Experiment 2:

### Machining Parameters:

Work piece: DIN 1.2344 (45 HRC)
Machining tool: Thread-cutting insert, fine-grained hard metal
Cutting speed: 330 rpm
Tooth advance: 0.18 mm/tooth
Radial feed: 50 mm
Axial feed: 2 mm

### Coolant: dry

Milling strategy: Lateral milling
Wear criterion: v_{bmax}>200 μm
Result (maximum life of coated tool):

| | |
|---|---|
| Commercial coating | 1.2 m |
| Al₆₀Nb₄₀N | 2.0 m |

1. A wear protection layer for tools such as milling cutters, cutting inserts, injection molds and the like, in particular wear protection layers deposited using physical vapor deposition (PVD), said layers having the general composition AlNbX, where X stands for N, C, B, CN, BN, CBN, NO, CO, BO, CNO, BNO, or CNCO, characterized in that the Nb fraction is less than 40 at % and/or the aluminum powder used in the manufacturing process is mixed with 10 to 50 at % zirconium relative to the aluminum.

2. The wear protection layer as recited in claim 1, characterized in that the wear protection layer has the following composition:
Nb_{1-a-b}Alₐ(Si_{b})X,
where
X stands for at least one element from the group N, C, B, CN, BN, CBN, NO, CO, BO, CNO, BNO, and CNCO and
the ranges for a and b are:
0.6<a≦0.9
0≦b≦0.2.

3. The wear protection layer as recited in claim 1, characterized in that the wear protection layer has the following composition:
Nb_{1-a-b}(Al_{1-c}Zr_{c})ₐ(Si_{b})X,
where
X stands for N, C, B, CN, BN, CBN, NO, CO, BO, CNO, BNO, or CNCO, and
0.3<a≦0.9
0≦b≦0.2
0.1<c≦0.5.

4. The wear protection layer as recited in claim 1 and/or 3, characterized in that 20 to 30 at % of zirconium is added to the aluminum powder.

5. The wear protection layer as recited in claim 4, characterized in that 25 at % of zirconium is mixed into the aluminum powder so that it is possible to form an intermetallic phase of Al3Zr with an atomic ratio of 75 at % aluminum and 25 at % zirconium.

6. A method for manufacturing a wear protection layer as recited in one of the preceding claims, characterized in that in order to deposit the layer on a tool, a target arc is vaporized; the target is essentially an AlNb target, which is vaporized in a reactive gas atmosphere; the ratio of Nb to Al is set so that the Nb content in the layer is between 10 and 40% and/or in order to manufacture the target, is mixed into the Al powder in a quantity of between 10 and 50 at % Zr.

7. The method as recited in claim 6, characterized in that between 20 and 30 at % Zr is mixed into the aluminum powder.

8. The method as recited in claim 6 or 7, characterized in that the atomic ratio of aluminum to zirconium is 75 at % to 25 at %.

9. The method as recited in one of claims 6 through 8, characterized in that the target is mixed so that the wear protection layer deposited by arc vaporization has the following composition:
Nb_{1-a-b}Alₐ(Si_{b})X,
where
X is at least one element from the group N, C, B, CN, BN, CBN, NO, CO, BO, CNO, BNO, and CNCO and
the ranges for a and b are:
0.6<a≦0.9
0≦b≦0.2.

10. The method as recited in one of claims 6 through 9, characterized in that the target is mixed so that the wear protection layer deposited by arc vaporization has the following composition:
Nb_{1-a-b}(Al_{1-c}Zr_{c})ₐ(Si_{b})X,
where
X stands for N, C, B, CN, BN, CBN, NO, CO, BO, CNO, BNO, or CNCO, and
0.3<a≦0.9
0≦b≦0.2
0.1<c≦0.5.

11. The method as recited in one of claims 6 through 10, characterized in that in order to adjust the melting points of the Nb and the aluminum, first an intermetallic aluminum zirconium phase mixture is produced, with a zirconium content of between 10 and 15 at % zirconium, preferably between 20 and 30 at % zirconium, and particularly preferably 25 at % zirconium.

12. A use of a wear protection layer as recited in one of claims 1 through 5, manufactured with a method as recited in one of claims 6 through 11 for milling tools such as hob cutters, ball-end mills, planar or profile cutters, reaming tools, reamers, thread-cutting inserts, casting molds, or injection molds.
